(19) United States
(12) Patent Application Publication
(10) Pub. No.: US 2014/0192337 A1
(43) Pub. Date: Jul. 10, 2014

(54) LITHOGRAPHIC APPARATUS, METHOD OF SETTING UP A LITHOGRAPHIC APPARATUS AND DEVICE MANUFACTURING METHOD

(71) Applicants: Arno Jan Bleeker, Westerhoven (NL); Erik Roelof Loopstra, Eindhoven (NL); Harmen Klaas Van Der Schoot, Vught (NL); Danny Maria Hubertus Philips, Son en Breugel (NL); Ruud Antonius Catharina Maria Beerens, Roggel (NL)

(72) Inventors: Arno Jan Bleeker, Westerhoven (NL); Erik Roelof Loopstra, Eindhoven (NL); Harmen Klaas Van Der Schoot, Vught (NL); Danny Maria Hubertus Philips, Son en Breugel (NL); Ruud Antonius Catharina Maria Beerens, Roggel (NL)

(73) Assignee: ASML Netherlands B.V., Veldhoven (NL)

(21) Appl. No.: 14/236,299

(22) PCT Filed: Jul. 24, 2012
(86) PCT No.: PCT/EP2012/064452

§ 371 Date: Jan. 30, 2014

Related U.S. Application Data
(60) Provisional application No. 61/529,032, filed on Aug. 30, 2011.
(60) Provisional application No. 61/541,574, filed on Sep. 30, 2011.
(60) Provisional application No. 61/583,980, filed on Jan. 6, 2012.

(51) Int. Cl. G03F 7/20

(52) U.S. Cl. CPC G03F 7/70641
USPC 355/55

(57) ABSTRACT

A lithographic apparatus having a programmable patterning device and a projection system. The programmable patterning device is configured to provide a plurality of radiation beams. The projection system has a lens group array configured to project the plurality of radiation beams onto a substrate. The projection system further includes a focus adjuster in an optical path corresponding to a lens group of the lens group array. The focus adjuster has an optical element having substantially zero optical power.

### CROSS-REFERENCE TO RELATED APPLICATIONS

This application claims the benefit of U.S. provisional application 61/529,032, which was filed on Aug. 30, 2011 and which is incorporated herein in its entirety by reference. This application also claims the benefit of U.S. provisional application 61/541,574, which was filed on Sep. 30, 2011 and which is incorporated herein in its entirety by reference. And also claims the benefit of U.S. provisional application 61/583,980, which was filed on Jan. 6, 2012 and which is incorporated herein in its entirety by reference.

### FIELD

The present invention relates to a lithographic apparatus, a method of setting up a lithographic apparatus and a method for manufacturing a device.

### BACKGROUND

A lithographic apparatus is a machine that applies a desired pattern onto a substrate or part of a substrate. A lithographic apparatus may be used, for example, in the manufacture of integrated circuits (ICs), flat panel displays and other devices or structures having fine features. In a conventional lithographic apparatus, a patterning device, which may be referred to as a mask or a reticle, may be used to generate a circuit pattern corresponding to an individual layer of the IC, flat panel display, or other device). This pattern may transferred on (part of) the substrate (e.g. silicon wafer or a glass plate), e.g. via imaging onto a layer of radiation-sensitive material (resist) provided on the substrate.

Instead of a circuit pattern, the patterning device may be used to generate other patterns, for example a color filter pattern, or a matrix of dots. Instead of a conventional mask, the patterning device may comprise a patterning array that comprises an array of individually controllable elements that generate the circuit or other applicable pattern. An advantage of such a “maskless” system compared to a conventional mask-based system is that the pattern can be provided and/or changed more quickly and for less cost.

Thus, a maskless system includes a programmable patterning device (e.g., a spatial light modulator, a contrast device, etc.). The programmable patterning device is programmed (e.g., electronically or optically) to form the desired patterned beam using the array of individually controllable elements. Types of programmable patterning devices include micro-mirror arrays, liquid crystal display (LCD) arrays, grating light valve arrays, arrays of self-emissive contrast devices and the like.

### SUMMARY

A maskless lithographic apparatus may be provided with, for example, an optical column capable of creating a pattern on a target portion of a substrate. The optical column may be provided with: a self emissive contrast device configured to emit a beam and a projection system configured to project at least a portion of the beam onto the target portion. The apparatus may be provided with an actuator to move the optical column or a part thereof with respect to the substrate. Thereby, the beam may be moved with respect to the substrate. By switching “on” or “off” the self-emissive contrast device during the movement, a pattern on the substrate may be created.

In a lithographic process, the image projected onto a substrate should be accurately focused. In particular, in some maskless lithography arrangements, the focusing range may be relatively small in comparison to a mask based system with the same critical dimension. For example, in a maskless system, a plurality of lenses may each be used to project spots of radiation onto the substrate, resulting in a relatively small focusing range. Therefore, there may be provided a system to adjust the focus by adjusting the position of the substrate relative to the projection system in a direction parallel to the optical axis of the projection system. However, it may be difficult to obtain the desired accuracy of the focusing system.

It is therefore, for example, desirable to provide an improved focusing system.

According to an embodiment of the invention, there is provided a lithographic apparatus, comprising a programmable patterning device and a projection system. The programmable patterning device is configured to provide a plurality of radiation beams. The projection system comprises a lens group array configured to project the plurality of radiation beams onto a substrate. The projection system further comprises at least one focus adjuster in an optical path corresponding to a lens group of the lens group array. The focus adjuster comprises an optical element having substantially zero optical power.

According to an embodiment of the invention, there is provided a lithographic apparatus comprising an optical component connected to a frame; and a radiation outlet configured to irradiate a surface of the frame so as to at least partially melt a portion at and near the surface of the frame so that the portion contracts as it cools, thereby adjusting the position and/or orientation of the optical component.

According to an embodiment of the invention, there is provided a method of setting up a lithographic apparatus. The lithographic apparatus comprises a programmable patterning device and a projection system. The programmable patterning device is configured to provide a plurality of radiation beams. The projection system comprises a lens group array configured to project the plurality of radiation beams onto a substrate. The method comprises measuring, for each of a plurality of lens groups of the lens group array, a parameter of an optical path corresponding to the lens group, and providing in each optical path a focus adjuster. The focus adjuster comprises an optical element having substantially zero optical power.

According to an embodiment of the invention, there is provided a device manufacturing method comprising providing a plurality of radiation beams, and projecting the plurality of radiation beams onto a substrate through a lens group array. The plurality of radiation beams are projected onto the substrate via at least one focus adjuster. The focus adjuster comprises an optical element having substantially zero optical power. The focus adjuster is in an optical path of a corresponding lens group of the lens group array.

According to an embodiment of the invention, there is provided a method of adjusting a position and/or orientation of an optical component, connected to a frame, of a lithographic apparatus comprising: irradiating a surface of the frame so as to at least partially melt a portion at and near the surface of the frame so that the portion contracts as it cools, thereby adjusting the position and/or orientation of the optical component.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a part of a lithographic apparatus according to an embodiment of the invention;

FIG. 2 depicts a top view of a part of the lithographic apparatus of FIG. 1 according to an embodiment of the invention;

FIG. 3 depicts a highly schematic, perspective view of a part of a lithographic apparatus according to an embodiment of the invention;

FIG. 4 depicts a schematic top view of projections by the lithographic apparatus according to FIG. 3 onto a substrate according to an embodiment of the invention;

FIG. 5 depicts an arrangement of a system to control focus according to an embodiment of the invention;

FIG. 6 depicts an arrangement of a system to control focus and imaging lens placement (height and in-plane) errors according to an embodiment of the invention;

FIG. 7 depicts an arrangement of a system to control focus and imaging lens placement (height and in-plane) errors according to an embodiment of the invention;

FIG. 8 schematically depicts an arrangement of a spot focus sensor system;

FIG. 9 depicts an arrangement of a system to control focus and imaging lens placement errors according to an embodiment of the invention;

FIG. 10 depicts an arrangement of a system to control focus and imaging lens placement errors according to an embodiment of the invention;

FIG. 11 schematically depicts an arrangement of focus adjusters according to an embodiment of the invention;

FIG. 12 schematically depicts the mechanism by which a supporting component may be bent by a laser according to an embodiment of the invention;

FIG. 13 schematically depicts the mechanism by which a frame may be contracted by irradiation according to an embodiment of the invention;

FIG. 14 schematically depicts an arrangement of optical components on a frame according to an embodiment of the invention;

FIG. 15 schematically depicts an example of irradiation of a frame so as to adjust the position of an optical component according to an embodiment of the invention; and

FIG. 16 schematically depicts the effect of the irradiation depicted in FIG. 15.

### DETAILED DESCRIPTION

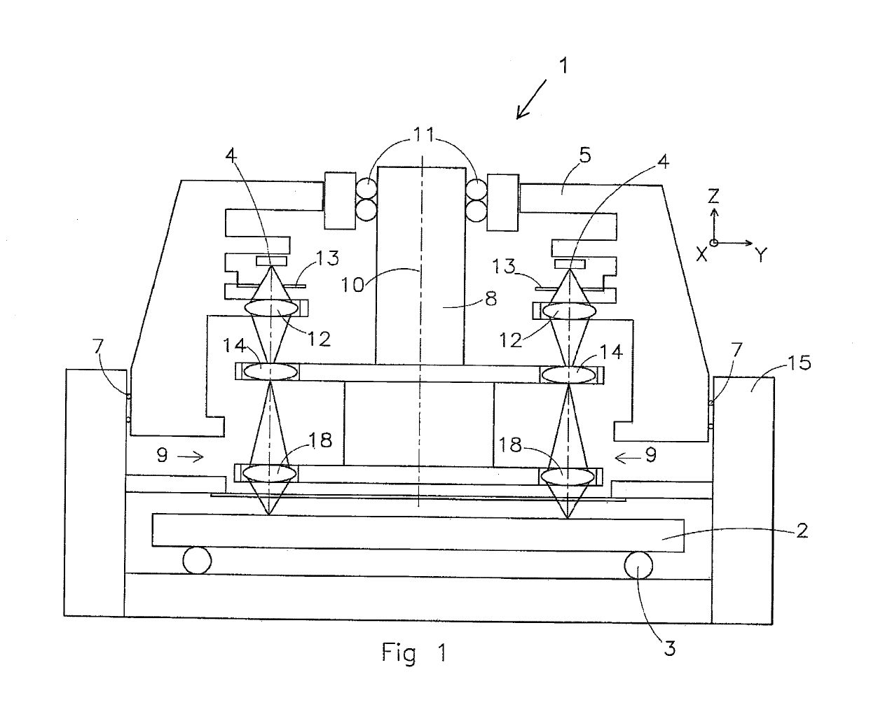

FIG. 1 schematically depicts a schematic cross-sectional side view of a part of a lithographic apparatus. In this embodiment, the lithographic apparatus has individually controllable elements substantially stationary in the X-Y plane as discussed further below although it need not be the case. The lithographic apparatus 1 comprises a substrate table 2 to hold a substrate, and a positioning device 3 to move the substrate table 2 in up to 6 degrees of freedom. The substrate may be a resist-coated substrate. In an embodiment, the substrate is a wafer. In an embodiment, the substrate is a polygonal (e.g. rectangular) substrate. In an embodiment, the substrate is a glass plate. In an embodiment, the substrate is a plastic substrate. In an embodiment, the substrate is a foil. In an embodiment, the lithographic apparatus is suitable for roll-to-roll manufacturing.

The lithographic apparatus 1 further comprises a plurality of individually controllable self-emissive contrast devices 4 configured to emit a plurality of beams. In an embodiment, the self-emissive contrast device 4 is a radiation emitting diode, such as a light emitting diode (LED), an organic LED (OLED), a polymer LED (PLED), or a laser diode (e.g., a solid state laser diode). In an embodiment, each of the individually controllable elements 4 is a blue-violet laser diode (e.g., Sanyo model no. DL-3146-151). Such diodes may be supplied by companies such as Sanyo, Nichia, Osram, and Nitride. In an embodiment, the diode emits UV radiation, e.g., having a wavelength of about 365 nm or about 405 nm. In an embodiment, the diode can provide an output power selected from the range of 0.5-200 mW. In an embodiment, the diode can provide an output power greater than 200 mW. In an embodiment, the size of laser diode (naked die) is selected from the range of 100-800 micrometers. In an embodiment, the laser diode has an emission area selected from the range of 0.5-5 micrometers². In an embodiment, the laser diode has a divergence angle selected from the range of 5-44 degrees. In an embodiment, the diodes have a configuration (e.g., emission area, divergence angle, output power, etc.) to provide a total brightness more than or equal to about 6.4×10⁸ W/(m²·sr).

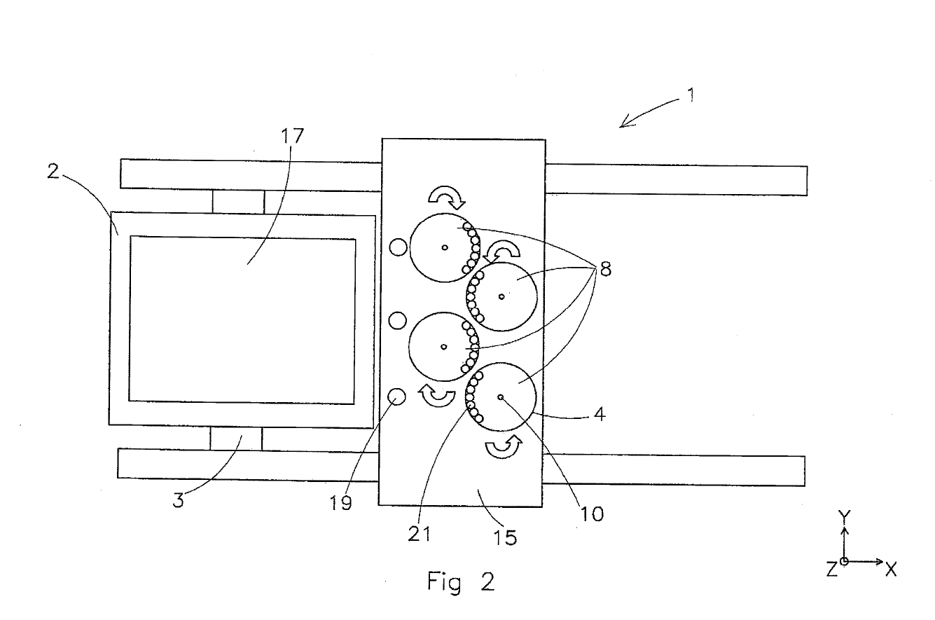

The self-emissive contrast devices 4 are arranged on a frame 5 and may extend along the Y-direction and/or the X direction. While one frame 5 is shown, the lithographic apparatus may have a plurality of frames 5 as shown in FIG. 2. Further arranged on the frame 5 is lens 12. Frame 5 and thus self-emissive contrast device 4 and lens 12 are substantially stationary in the X-Y plane. Frame 5, self-emissive contrast device 4 and lens 12 may be moved in the Z-direction by actuator 7. Alternatively or additionally, lens 12 may be moved in the Z-direction by an actuator related to this particular lens. Optionally, each lens 12 may be provided with an actuator.

The self-emissive contrast device 4 may be configured to emit a beam and the projection system 12, 14 and 18 may be configured to project the beam onto a target portion of the substrate. The self-emissive contrast device 4 and the projection system form an optical column. The lithographic apparatus 1 may comprise an actuator (e.g. motor) 11 to move the optical column or a part thereof with respect to the substrate. Frame 8 with arranged thereon field lens 14 and imaging lens 18 may be rotatable with the actuator. A combination of field lens 14 and imaging lens 18 forms movable lens group 9. In use, the frame 8 rotates about its own axis 10, for example, in the directions shown by the arrows in FIG. 2. The frame 8 is rotated about the axis 10 using an actuator e.g. motor 11. Further, the frame 8 may be moved in a Z direction by motor 7 so that the movable lens group 9 may be displaced relative to the substrate table 2. In an embodiment, the frame 8 may be moved in the X and Y directions by motor 7.

An aperture structure 13 having an aperture therein may be located above lens 12 between the lens 12 and the self-emissive contrast device 4. The aperture structure 13 can limit diffraction effects of the lens 12, the associated self-emissive contrast device 4, and/or of an adjacent lens 12/self-emissive contrast device 4.

The depicted apparatus may be used by rotating the frame 8 and simultaneously moving the substrate on the substrate table 2 underneath the optical column. The self-emissive contrast device 4 can emit a beam through the lenses 12, 14, and 18 when the lenses are substantially aligned with each other. By moving the lenses 14 and 18, the image of the beam on the substrate is scanned over a portion of the substrate. By simultaneously moving the substrate on the substrate table 2 underneath the optical column, the portion of the substrate which is subjected to an image of the self-emissive contrast device 4 is also moving. By switching the self-emissive contrast device 4 “on” and “off” (e.g., having no output or output below a threshold when it is “off” and having an output above a threshold when it is “on”) at high speed under control of a controller, controlling the rotation of the optical column or part thereof, controlling the intensity of the self-emissive contrast device 4, and controlling the speed of the substrate, a desired pattern can be imaged in the resist layer on the substrate. In an embodiment, the self-emissive contrast device may be switched between a plurality of different intensities under control of the controller.

FIG. 2 depicts a schematic top view of the lithographic apparatus of FIG. 1 having self-emissive contrast devices 4. Like the lithographic apparatus 1 shown in FIG. 1, the lithographic apparatus 1 comprises a substrate table 2 to hold a substrate 17, a positioning device 3 to move the substrate table 2 in up to 6 degrees of freedom, an alignment/level sensor 19 to determine alignment between the self-emissive contrast device 4 and the substrate 17, and to determine whether the substrate 17 is at level with respect to the projection of the self-emissive contrast device 4. As depicted the substrate 17 has a rectangular shape, however also or alternatively round substrates may be processed.

The self-emissive contrast device 4 is arranged on a frame 15. The self-emissive contrast device 4 may be a radiation emitting diode, e.g., a laser diode, for instance a blue-violet laser diode. As shown in FIG. 2, the self-emissive contrast devices 4 may be arranged into an array 21 extending in the X-Y plane.

The array 21 may be an elongate line. In an embodiment, the array 21 may be a single dimensional array of self-emissive contrast devices 4. In an embodiment, the array 21 may be a two dimensional array of self-emissive contrast device 4.

A rotating frame 8 may be provided which may be rotating in a direction depicted by the arrow. The rotating frame may be provided with lenses 14, 18 (show in FIG. 1) to provide an image of each of the self-emissive contrast devices 4. The apparatus may be provided with an actuator to rotate the optical column comprising the frame 8 and the lenses 14, 18 with respect to the substrate.

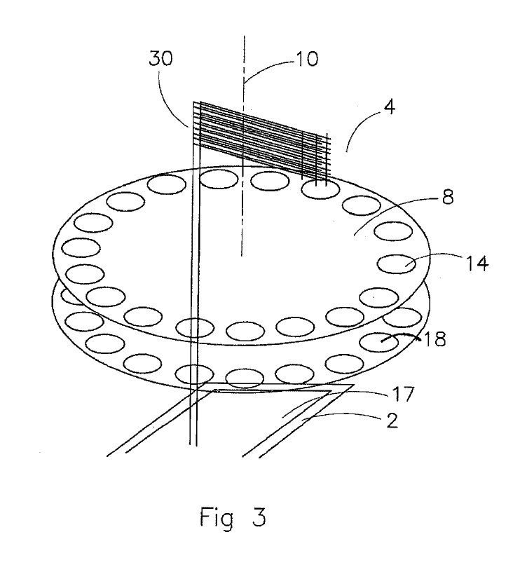

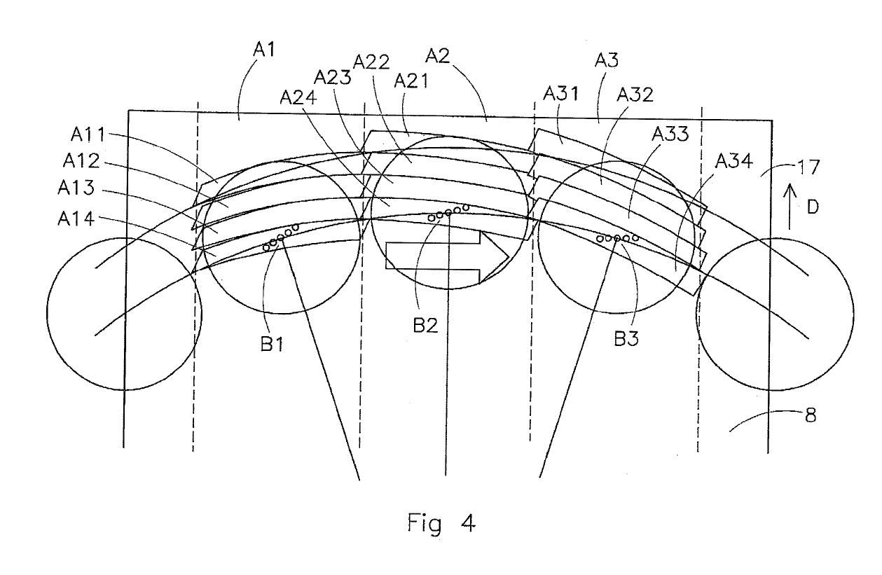

FIG. 3 depicts a highly schematic, perspective view of the rotating frame 8 provided with lenses 14, 18 at its perimeter. A plurality of beams, in this example 10 beams, are incident onto one of the lenses and projected onto a target portion of the substrate 17 held by the substrate table 2. In an embodiment, the plurality of beams are arranged in a straight line. The rotatable frame is rotatable about axis 10 by means of an actuator (not shown). As a result of the rotation of the rotatable frame 8, the beams will be incident on successive lenses 14, 18 (field lens 14 and imaging lens 18) and will, incident on each successive lens, be deflected thereby so as to travel along a part of the surface of the substrate 17, as will be explained in more detail with reference to FIG. 4. In an embodiment, each beam is generated by a respective source, i.e. a self-emissive contrast device, e.g. a laser diode (not shown in FIG. 3). In the arrangement depicted in FIG. 3, the beams are deflected and brought together by a segmented mirror 30 in order to reduce a distance between the beams, to thereby enable a larger number of beams to be projected through the same lens and to achieve resolution requirements to be discussed below.

As the rotatable frame rotates, the beams are incident on successive lenses and, each time a lens is irradiated by the beams, the places where the beam is incident on a surface of the lens, moves. Since the beams are projected on the substrate differently (with e.g. a different deflection) depending on the place of incidence of the beams on the lens, the beams (when reaching the substrate) will make a scanning movement with each passage of a following lens. This principle is further explained with reference to FIG. 4. FIG. 4 depicts a highly schematic top view of a part of the rotatable frame 8. A first set of beams is denoted by B1, a second set of beams is denoted by B2 and a third set of beams is denoted by B3. Each set of beams is projected through a respective lens set 14, 18 of the rotatable frame 8. As the rotatable frame 8 rotates, the beams B1 are projected onto the substrate 17 in a scanning movement, thereby scanning area A14. Similarly, beams B2 scan area A24 and beams B3 scan area A34. At the same time of the rotation of the rotatable frame 8 by a corresponding actuator, the substrate 17 and substrate table are moved in the direction D (which may be along the X axis as depicted in FIG. 2), thereby being substantially perpendicular to the scanning direction of the beams in the area's A14, A24, A34. As a result of the movement in direction D by a second actuator (e.g. a movement of the substrate table by a corresponding substrate table motor), successive scans of the beams when being projected by successive lenses of the rotatable frame 8, are projected so as to substantially abut each other, resulting in substantially abutting areas A11, A12, A13, A14 (areas A11, A12, A13 being previously scanned and A14 being currently scanned as shown in FIG. 4) for each successive scan of beams B1, resulting in substantially abutting areas A21, A22, A23 and A24 (areas A21, A22, A23 being previously scanned and A24 being currently scanned as shown in FIG. 4) for each successive scan of beams B2, and resulting in substantially abutting areas A31, A32, A33 and A34 (areas A31, A32, A33 being previously scanned and A34 being currently scanned as shown in FIG. 4) for each successive scan of beams B3. Thereby, the areas A1, A2 and A3 of the substrate surface may be covered with a movement of the substrate in the direction D while rotating the rotatable frame 8. The projecting of multiple beams through a same lens allows processing of a whole substrate in a shorter timeframe (at a same rotating speed of the rotatable frame 8), since for each passing of a lens, a plurality of beams scan the substrate with each lens, thereby allowing increased displacement in the direction D for successive scans. Viewed differently, for a given processing time, the rotating speed of the rotatable frame may be reduced when multiple beams are projected onto the substrate via a same lens, thereby possibly reducing effects such as deformation of the rotatable frame, wear, vibrations, turbulence, etc. due to high rotating speed. In an embodiment, the plurality of beams are arranged at an angle to the tangent of the rotation of the lenses 14, 18 as shown in FIG. 4. In an embodiment, the plurality of beams are arranged such that each beam overlaps or abuts a scanning path of an adjacent beam.

A further effect of the aspect that multiple beams are projected at a time by the same lens, may be found in relaxation of tolerances. Due to tolerances of the lenses (positioning, optical projection, etc), positions of successive areas A11, A12, A13, A14 (and/or of areas A21, A22, A23 and A24 and/or of areas A31, A32, A33 and A34) may show some degree of positioning inaccuracy in respect of each other. Therefore, some degree of overlap between successive areas A11, A12, A13, A14 may be required. In case of for example 10% of one beam as overlap, a processing speed would thereby be reduced by a same factor of 10% in case of a single beam at a time through a same lens. In a situation where there are 5 or more beams projected through a same lens at a time, the same overlap of 10% (similarly referring to one beam example above) would be provided for every 5 or more projected lines, hence reducing a total overlap by a factor of approximately 5 or more to 2% or less, thereby having a significantly lower effect on overall processing speed. Similarly, projecting at least 10 beams may reduce a total overlap by approximately a factor of 10. Thus, effects of tolerances on processing time of a substrate may be reduced by the feature that multiple beams are projected at a time by the same lens. In addition or alternatively, more overlap (hence a larger tolerance band) may be allowed, as the effects thereof on processing are low given that multiple beams are projected at a time by the same lens.

Alternatively or in addition to projecting multiple beams via a same lens at a time, interlacing techniques could be used, which however may require a comparably more stringent matching between the lenses. Thus, the at least two beams projected onto the substrate at a time via the same one of the lenses have a mutual spacing, and the lithographic apparatus may be arranged to operate the second actuator so as to move the substrate with respect to the optical column to have a following projection of the beam to be projected in the spacing.

In order to reduce a distance between successive beams in a group in the direction D (thereby e.g. achieving a higher resolution in the direction D), the beams may be arranged diagonally in respect of each other, in respect of the direction D. The spacing may be further reduced by providing a segmented mirror 30 in the optical path, each segment to reflect a respective one of the beams, the segments being arranged so as to reduce a spacing between the beams as reflected by the mirrors in respect of a spacing between the beams as incident on the mirrors. Such effect may also be achieved by a plurality of optical fibers, each of the beams being incident on a respective one of the fibers, the fibers being arranged so as to reduce along an optical path a spacing between the beams downstream of the optical fibers in respect of a spacing between the beams upstream of the optical fibers.

Further, such effect may be achieved using an integrated optical waveguide circuit having a plurality of inputs, each for receiving a respective one of the beams. The integrated optical waveguide circuit is arranged so as to reduce along an optical path a spacing between the beams downstream of the integrated optical waveguide circuit in respect of a spacing between the beams upstream of the integrated optical waveguide circuit.

A system may be provided to control the focus of an image projected onto a substrate. The arrangement may be provided to adjust the focus of the image projected by part or all of an optical column in an arrangement as discussed above.

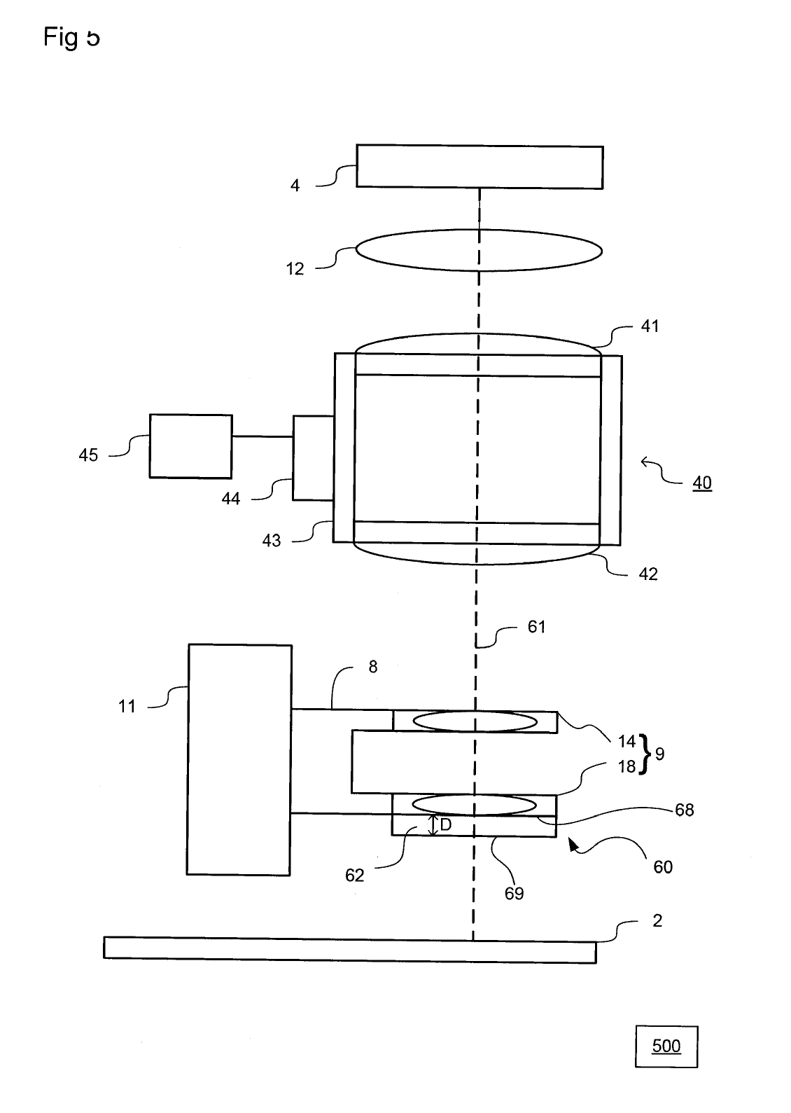

As depicted in FIG. 5, the focus adjustment arrangement may include a radiation beam expander 40 that is arranged such that the image of the programmable patterning device 4 projected onto the field lens 14, discussed above, is projected via the radiation beam expander 40. The field lens 14 and the imaging lens 18, discussed above, are arranged such that an image projected onto the field lens 14 is projected onto a substrate supported on the substrate table 2. Therefore, by adjusting the position, in a direction parallel to the optical path 61 of the projection system, of the image projected onto the field lens 14, the focus of the image formed at the level of the substrate may be adjusted. The optical path 61 of the projection system may be the optical axis of the projection system. As will be discussed further below, the radiation beam expander 40 is used to provide such an adjustment of the position of the image projected onto the field lens 14.

This may be advantageous because it means that focus adjustment may be performed without adjusting the position of the substrate relative to the projection system. This may enable accurate focus control independently for different areas located across the full width of the illumination field on the substrate. For example, each optical column, or part thereof, may have independent capability to adjust the focus of the image it is projecting onto the substrate.

Furthermore, such an arrangement may not require adjusting the position of the field lens 14 or the imaging lens 18 in a direction parallel to the optical path 61 of the projection system.

Such control may be difficult in an arrangement in which, as discussed above, the field lens 14 and the imaging lens 18 are arranged to move in a direction perpendicular to the optical path 61 of the projection system. For example, as depicted in FIG. 5, and consistent with the arrangements discussed above, the field lens 14 and the imaging lens 18 may be mounted to a rotating frame 8 that is driven by a first actuator system 11.

The radiation beam expander 40 may be formed from a pair of axially aligned positive lenses 41,42. The lenses 41,42 may be fixedly positioned relative to each other, for example by means of a rigid support frame 43.

In an embodiment, the radiation beam expander 40 may be configured such that it is both object-space telecentric and image-space telecentric. It will be understood that, by object-space telecentric, it is meant that the entrance pupil is located at infinity and, by image-space telecentric, it is meant that the exit pupil is located at infinity.

A second actuator system 44 may be provided and arranged in order to control the position of the radiation beam expander 40 in a direction parallel to the may be configured to act on the support frame 43 in order to adjust the position of the first and second lens 41,42 relative to the field lens 14 while maintaining the relative positions of the first and second lenses 41,42.

The second actuator system 44 may particularly be configured in order to help ensure that the radiation beam expander 40 only moves in a direction parallel to the optical path 61 and such that there is substantially no movement of the radiation beam expander 40 in a direction perpendicular to the optical path 61 of the projection system. Movement of the radiation beam expander 40 in the direction parallel to the optical path 61 of the projection system is used to adjust the position of the image of the programmable patterning device 4 projected onto the field lens 14.

A controller 45 may be provided that is adapted to control the second actuator 44 in order to move the radiation beam expander 40 in an appropriate manner in order to provide the desired focus control of the image projected onto the substrate. In particular, movement of the radiation beam expander 40 along the optical path 61 of the projection system is proportional to the consequent focus shift at the substrate. Accordingly, the controller may store a certain multiple for the system and use this to convert a desired focus shift at the substrate to an appropriate movement of the radiation beam expander 40. Subsequently, the controller 45 may control the second actuator system 44 in order to provide the desired movement.

The desired focus shift at the level of the substrate may be determined, for example, from a measurement of the position of the substrate and/or substrate table 2, in conjunction with a measurement of the distortion of the upper surface of the substrate at a target portion on which an image is to be projected. This may be combined with previously determined information regarding the spot focus of each of the beams of radiation projected onto the substrate. The distortions of the upper surface of the substrate may be mapped prior to exposure of the pattern on the substrate and/or may be measured for each portion of the substrate immediately before the pattern is projected onto that portion of the substrate.

The multiple relating the movement of the radiation beam expander 40 to the focus shift at the substrate may be determined by the formula below

(1/B²)/(A²−1)

in which A is the magnification of the radiation beam expander 40 and B is the magnification of the optical system from the lens 14 onto which the radiation beam expander projects an image of the programmable patterning device, to the substrate, namely the magnification of the combination of the field lens 14 and the imaging lens 18.

In an arrangement, the magnification of the combined system of the field lens 14 and the imaging lens 18 may be 1/15 (i.e. demagnification) and the magnification of the radiation beam expander 40 may be 2. Accordingly, using the formula above, it will be seen that for a focus shift of 25 μm at the level of the substrate, the associated movement of the radiation beam expander is 1.875 mm.

As noted above, the focusing arrangement may be provided separately for each optical column within a lithographic apparatus. Accordingly, each optical column may include a respective radiation beam expander 40 and associated actuator system 44 arranged to move the respective radiation beam expander 40 in a direction parallel to the optical path 61 of the projection system.

The radiation beam expander 40 is an optional feature of the focus control system described herein. In an embodiment the focus control system does not comprise the radiation beam expander 40.

As depicted in FIG. 5, the projection system comprises at least one focus adjuster 60. The focus adjuster 60 is in the optical path 61 corresponding to a lens group 9 of the lens group array. The focus adjuster 60 comprises an optical element 62. The optical element 62 has substantially zero optical power.

The optical path 61 starts at the programmable patterning device and ends at the substrate 17. The programmable patterning device is at the upstream end of the optical path 61. The substrate 17 is at the downstream end of the optical path 61.

The focus adjuster 60 is configured to adjust a parameter of the optical path 61. The focus adjuster 60 can correct and/or compensate for an undesirable difference between the actual position of the lens group 9 and the target position of the lens group 9. The focus adjuster 60 can correct and/or compensate for an undesirable variation between the material(s) of the lenses 14, 18 of a lens group 9 and the material(s) of the lenses 14, 18 of a different lens group 9 of the lens group array.

Without the focus adjuster 60, the field lenses 14 should be placed relative to each other with a lens-to-lens accuracy of within a few microns (or even 0.1 micrometers), and the imaging lenses 18 should be placed relative to each other with a lens-to-lens accuracy of within 0.1 micrometers. The accuracy of the positions of the lenses is to provide the desired accuracy of angular separation of the radiation beams that pass through the lenses. The angular separation should be accurate for the lithographic apparatus 1 to provide an accurate pattern, for example, on the substrate 17. It is desirable for all of the lenses to have the same focal length. In the radial direction, the focal position of a lens with respect to a focal position of a neighboring lens is significant in order to avoid gaps in the writing grid. This lens-to-lens accuracy may be very difficult to achieve. The use of the focus adjuster 60 makes it easier to manufacture the lithographic apparatus 1 with the desired focal accuracy.

The field lenses 14 and the imaging lenses 18 should be positioned on the frame 8 of the lithographic apparatus 1 within the appropriate accuracy in both the radial direction and the axial direction. The axial direction corresponds to the direction of the axis 10 of the frame 8. The radial direction is perpendicular to the axial direction. Mechanical tolerances make it difficult to place the lenses 14, 18 with the appropriate accuracy.

Additionally, variations in the materials of the optical components of the lens groups 9 may undesirably affect the optical positioning. In particular, the focal lengths of the lens groups 9 may vary undesirably among the lens groups 9. Additionally, the focal position on the substrate 17 of the optical paths that the radiation beams follow through the lens groups 9 may undesirably vary from the target focal positions. This results in undesirable discrepancies in the angular separation of radiation beams that pass through the lens groups 9. The use of the focus adjuster 60 may overcome one or more of these problems.

In an embodiment the focus adjuster 60 is configured to adjust a focal length f of the optical path 61. The adjustment of the focal length f of the optical path 61 by the focus adjuster 60 depends on the thickness of the optical element 62 of the focus adjuster 60, and also depends on the refractive index n of the material of the optical element 62.

In an embodiment the focus adjuster 60 is configured such that the focal length adjustment df increases as the thickness D of the optical element 62 increases. In an embodiment the focus adjuster 60 is configured such that the focal length adjustment df increase as the refractive index of the material of the optical element 62 increases, where the refractive index n is greater than 1. In an embodiment the focal length adjustment df caused by the focus adjuster 60 is given at least approximately by the following formula:

$$df = D ( \frac{n - 1}{n} )$$

The focal length adjustment df can be used to correct for an undesirable difference between the actual position of the lenses 14, 18 of the lens group 9 and their target positions. The thickness D of the optical element 62 of the focus adjuster 60 can be chosen so as to achieve the desired focal length adjustment df.

In an embodiment the focus adjuster 60 is configured to adjust the focal length f of the optical path 61 to be substantially equal to the focal length of an optical path of a different lens group of the lens group array. The focus adjuster 60 can be used to achieve uniform focal lengths among different lens groups 9 of the lens group array.

In an embodiment the projection system comprises a plurality of focus adjusters 60. Each focus adjuster 60 is in a corresponding optical path 61 corresponding to a lens group 9 of the lens group array. In an embodiment each and every lens group 9 of the lens group array comprises a focus adjuster 60. Each focus adjuster 60 can be configured to have an optical element 62 of the thickness D such that the focal length for the corresponding lens group 9 is equal to a target focal length. The focal length f of the lens groups 9 can be uniform among the lens group array by using the focus adjusters 60.

In an embodiment the optical element 62 comprises an entry surface 68 and an exit surface 69. The radiation beams enter the optical element 62 through the entry surface 68. The radiation beams exit the optical element 62 through the exit surface 69. In an embodiment the entry surface 68 and the exit surface 69 are substantially flat surfaces. In an embodiment the entry surface 68 is substantially parallel to the exit surface 69. The optical element 62 may be substantially flat.

The optical element 62 has substantially zero optical power. Optical power is the degree to which an optical component converges or diverges radiation. In isolation the optical element 62 of the focus adjuster 60 neither converges nor diverges radiation. However, the focus adjuster 60 has an effect on the focal length f of the projection system that it is a part of. The optical element 62 of the focus adjuster 60 causes only minimal color variation, if any, of the radiation beam.

In an embodiment the optical element 62 of the focus adjuster 60 is configured to be the last optical element in the optical path 61. In an embodiment the optical element 62 is positioned between the imaging lens 18 and the substrate 17. The imaging lens 18 may be the last lens of the projection system. It is not necessary for the optical element 62 of the focus adjuster 60 to be the last optical element in the optical path 61. For example, in an embodiment the optical element 62 may be positioned between the imaging lens 18 and the field lens 14 of the projection system. In another embodiment the optical element 62 of the focus adjuster 60 may be positioned upstream of the field lens 14 of the lens group 9. However, the focus adjuster 60 more effectively adjusts the focal length f and/or focal position of the optical path 61 by being positioned as the last optical element in the optical path 61.

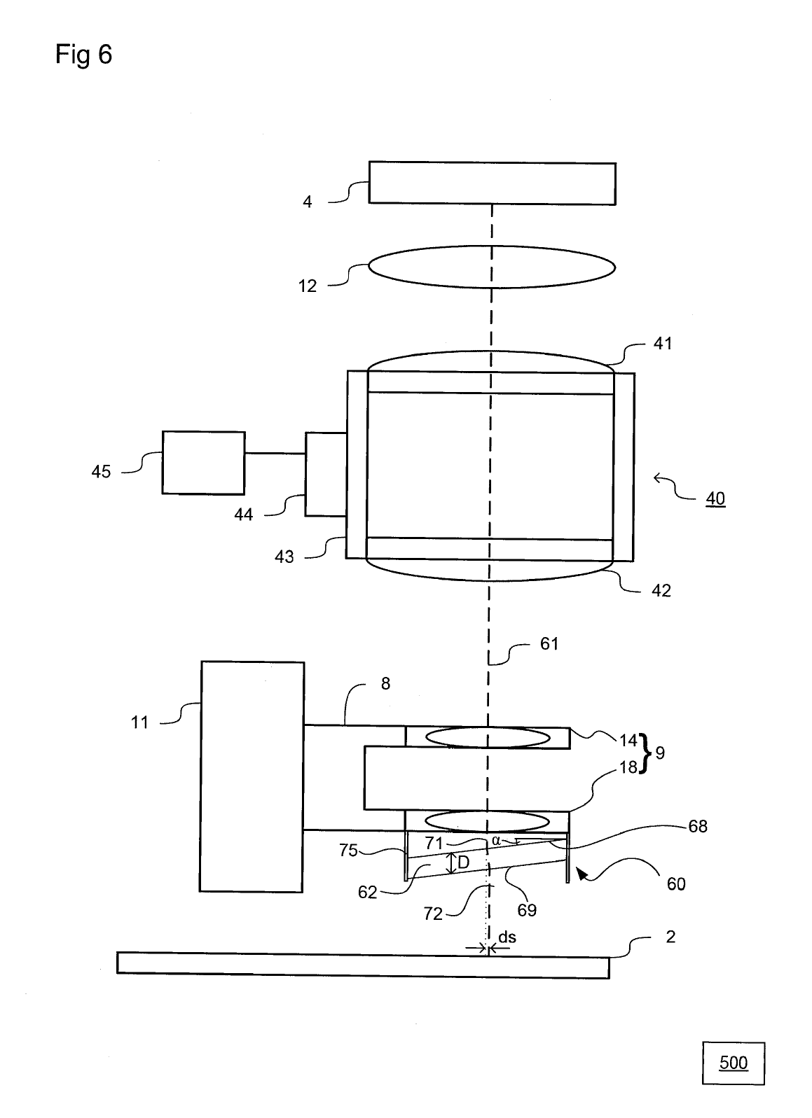

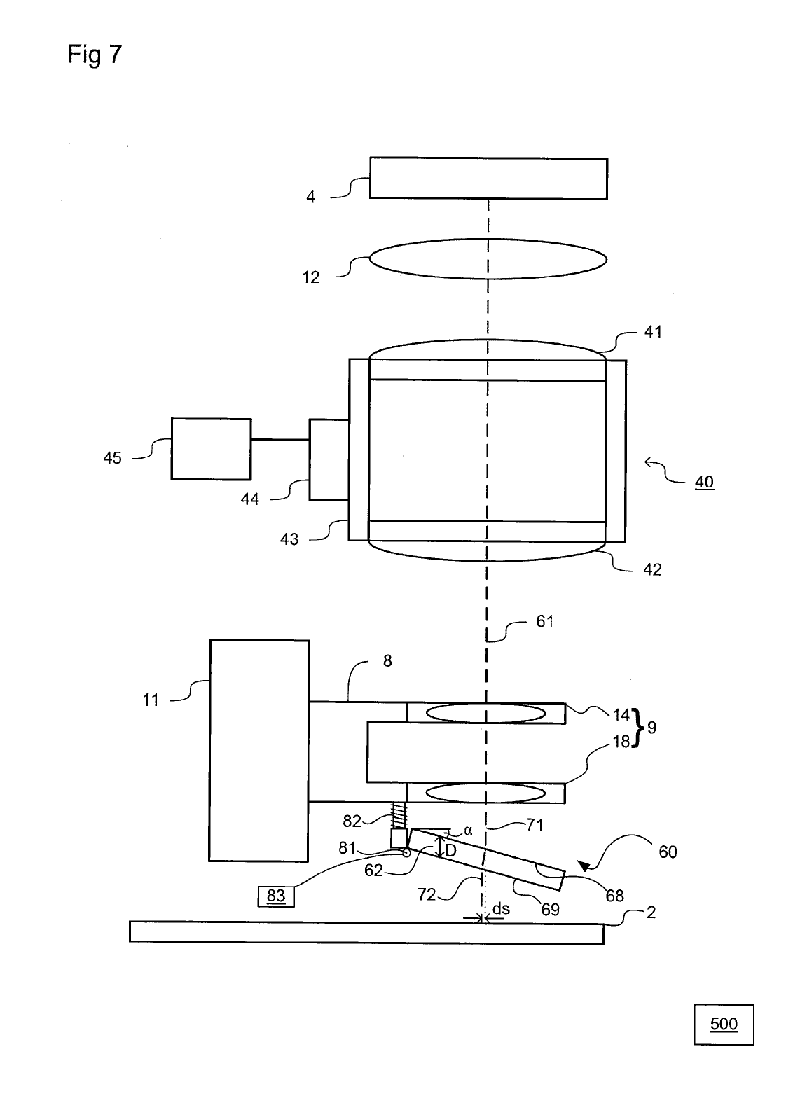

As depicted in FIG. 6 and FIG. 7, in an embodiment the focus adjuster 60 is configured to adjust a focal position of the optical path 61. The focal position of the optical path 61 is the position at which the radiation beam that passes through the lens group 9 comes into contact with the substrate 17. The focal position depends on the angle at which the radiation beam exits the projection system. In an embodiment the focus adjuster 60 is configured to shift the optical path 61. The shifting of the optical path 61 does not affect the telecentricity of the optical path 61, which is maintained. In an embodiment, a window of a vacuum compartment is positioned between the focus adjuster 60 and the substrate 70.

In an embodiment the optical element 62 of the focus adjuster 60 is tilted with respect to the optical path 61. In particular, the optical element 62 of the focus adjuster 60 may be tilted with respect to a plane perpendicular to an immediately upstream section 71 of the optical path 61. The optical element 62 is tilted with respect to the lens group 9 such that the optical element 62 is not parallel with the lenses 14, 18 of the lens group 9. The tilt of the optical element 62 results in an adjustment of the focal position of the optical path 61. This focal position adjustment ds corrects for lateral (e.g. radial) displacement of the lenses 14, 18 of the lens group 9 away from their target lateral positions. The focal position adjustment ds depends on the thickness D of the optical element 62, the refractive index n of the material of the optical element 62 and the tilt angle α of the optical element 62. In an embodiment, the focus adjuster 60 is configured to shift the focal position of the optical path 61 by a distance ds. The optical path 61 immediately upstream of the focus adjuster 60 is substantially parallel with the optical path 61 immediately downstream of the focus adjuster 60.

In an embodiment the focus adjuster 60 is configured such that the focal position adjustment ds increases with increasing tilt angle α. In an embodiment the focus adjuster 60 is configured such that the focal position adjustment ds increases with increasing thickness D of the optical element 62. In an embodiment the focus adjuster 60 is configured such that the focal position adjustment ds increases with increasing refractive index n of the material of the optical element 62, where the refractive index n is greater than 1. In particular, the focal position adjustment ds provided by the focus adjuster 60 is given approximately by the formula below.

$$ds = α D ( \frac{n - 1}{n} )$$

The focal position adjustment ds is the distance between the position of focus of the radiation beam when the focus adjuster 60 is not used and the position of focus of the radiation beam when the focus adjuster 60 is used. The tilt angle α is measured in radians.

In an embodiment the focus adjuster 60 is attached to a frame. The frame may be provided with the lens group array. In an embodiment the focus adjuster 60 is attached to the frame 8 to which the lens group array is fixed. This allows the focus adjuster 60 to move with the lens group 9 when the lens group 9 is moved by the motor 11. The position of the focus adjuster 60 relative to the lens group 9 can be kept constant during use of the lithographic apparatus 1.

In an embodiment the focus adjuster 60 is attached to the frame 8 such that the optical element 62 is fixed at a tilted orientation with respect to the optical path 61. In an embodiment the tilt angle α is fixed and cannot be adjusted during use of the lithographic apparatus. The tilt angle α can be chosen when setting up the lithographic apparatus 1. The tilt angle α can be chosen so as to correct the focal position of the optical path 61. The tilt angle is the angle between the plane perpendicular to the optical axis of the lens group and the direction of greatest gradient of the entry surface 68 of the optical element 62. The gradient is measured relative to the plane perpendicular to the optical axis of the lens group 9.

FIG. 6 depicts a focus system according to an embodiment of the invention. The optical element 62 of the focus adjuster 60 is tilted with respect to the optical path 61 corresponding to the lens group 9. In particular the optical element 62 is positioned at an oblique angle to the immediately preceding upstream portion 71 of the optical path 61. The optical element 62 is configured to shift the optical path 61. The immediately downstream portion 72 of the optical path 61 is directed in a different direction from that of the immediately upstream portion 71 of the optical path 61.

In the embodiment depicted in FIG. 6, the tilt angle α is fixed. As depicted in FIG. 6, in an embodiment the focus adjuster 60 comprises a tube 75. The tube 75 extends along the optical path 61. The tube 75 is elongate. The direction of elongation is substantially parallel to the optical path 61. The tube 75 houses the optical element 62 fixedly tilted with respect to the optical path 61.

In an embodiment the optical element 62 is fixed relative to the tube 75 of the focus adjuster 60. In an embodiment the tube 75 is attached to the frame 8 that includes the lens group array. In an embodiment the tube 75 is attached to the imaging lens 18. The focus adjuster 60 can be attached to the lithographic apparatus 1 when setting up the lithographic apparatus 1.

An embodiment of the invention provides a method of setting up a lithographic apparatus 1. As above, in an embodiment the lithographic apparatus 1 comprises a programmable patterning device configured to provide a plurality of radiation beams, and a projection system comprising a lens group array configured to project the plurality of radiation beams onto a substrate 17.

The setting up method comprises measuring, for each of a plurality of lens groups 9 of the lens group array, a parameter of an optical path 61 corresponding to the lens group 9, and providing in each optical path 61 a focus adjuster 60. In an embodiment the focus adjuster 60 is configured to adjust the measured parameter of the optical path 61. The focus adjuster 60 can be used to correct the parameter of the optical path to be equal to a target value of that parameter.

In an embodiment the parameter is the focal length f of the optical path 61. As explained above, the focus adjuster 60 can increase the focal length f of the optical path 61. In an embodiment the parameter is a focal position of the optical path 61. The focus adjuster can shift the focal position as explained above.

During the measuring, a deviation of the parameter (e.g. the focal length f and/or focal position of the optical path 61) from a target value can be measured. Subsequently, a parameter of the focus adjuster 60 such as the thickness D, its axial position, the refractive index n of the material of the optical element 62 and/or the tilt angle α, can be selected so as to correct for the measured deviation. In an embodiment a controller 500 determines a suitable value for one or more selected from: the tilt angle α, thickness D, axial position and/or refractive index n, of the optical element 62 of the focus adjuster 60.

Once the parameter(s) of the focus adjuster 60 has been chosen, the tuned focus adjuster 60 is attached to the lithographic apparatus 1. As depicted in FIG. 6 the focus adjuster 60 may be attached to the frame 8 of the lithographic apparatus 1.

In an embodiment one or more of the parameters of the focus adjuster 60 may be chosen independently of the measurements of the deviation of a parameter of the optical path 61. For example, the refractive index n of the material of the optical element 62 may be chosen independently of the measurement. The material of the optical element 62 may be a glass, such as a fused quartz. This has a refractive index n of approximately 1.5.

In an embodiment the axial position of the optical element 62 may be chosen independently of the measurement. Each focus adjuster 60 may comprise an optical element 62 housed inside a tube 75 at a fixed distance from the upstream end of the tube 75.

In an embodiment the tilt angle α of the optical element 62 may be chosen independently of the measurement. In this case it is still possible to vary the focal position adjustment ds at least in one direction as required, even though as explained above the focal position adjustment ds depends on the tilt angle. For example, it may be desired to adjust the focal position in the radial direction of the projection system. Here, the radial direction is taken to mean the direction of a radius of the wheels (depicted in FIG. 3) to which the field lenses 14 and imaging lenses 18 are attached. Accuracy of the focal position in the radial direction is more important than accuracy of the focal position in the azimuthal direction. The azimuthal direction is the tangential direction of the wheel, which is in the same plane as the radial direction but is always perpendicular to the radial direction. The azimuthal or tangential focal position may be corrected via modulation timing of the self-emissive contrast devices.

When attaching the focus adjuster 60 to the frame 8, the orientation of the focus adjuster 60 can be selected depending on the desired amount of focal position adjustment ds in the radial direction. The focal position adjustment in the radial direction is at its maximum for that focus adjuster 60 when the direction of the gradient of the tilted optical element 62 is aligned with the radial direction. The direction of the gradient is the direction in which the gradient of the surfaces 68, 69 of the optical element 62 is at its maximum. When the direction of the gradient is perpendicular to the radial direction, the focus adjuster 60 has no effect on the focal position in the radial direction.

Hence, the tilt angle α of the optical element 62 within the tube 75 can be chosen to correspond to the maximum radial tilt angle for focal position adjustment in the radial direction. If the actual focal position adjustment ds in the radial direction is less than the maximum, the orientation of the focus adjuster 60 can be chosen such that the radial tilt angle of the optical element 62 results in the desired amount of focal position adjustment in the radial direction. The radial tilt angle is the angle between the plane perpendicular to the optical axis of the lens group 9 and the entry surface 68 of the optical element 62 in the radial direction.

When the direction of the gradient of the optical element 62 is not aligned with the radial direction, the focus adjuster 60 will provide a focal positional shift in the azimuthal direction in addition to a focal position adjustment in the radial direction. In an embodiment the tilt angle α of the optical element 62 in the tube 75 is fixed independently of the measurement and the focal position adjustment ds in the radial direction is controlled by controlling the orientation of the direction of the gradient of the optical element 62 with respect to the radial direction. In this case, the focal position adjustment in the azimuthal direction cannot be controlled and takes a value that inevitably results from the other constraints of the system. However, it may be more important to control the radial focal position than the azimuthal focal position. In an embodiment the controller 500 is configured to compensate for variation in the azimuthal focal position by controlling one or more other parameters in the lithographic apparatus, such as the self-emissive contrast device timing.

In an embodiment the orientation of the focus adjuster 60 with respect to the lens group 9 cannot be adjusted during use of the lithographic apparatus 1. The orientation of the focus adjuster 60 is selected during setting up of the lithographic apparatus 1, after which the focus adjuster 60 is fixed to the lithographic apparatus 1.

In an embodiment the optical element 62 is rotatable about the optical path 61 as the axis of rotation. In this case, the orientation of the direction of the gradient of the optical element 62 relative to the radial direction can be adjusted during use of the lithographic apparatus 1. This makes it possible to use the focus adjuster 60 to make further adjustments to the focal position of the optical path 61 as required even after setting up the lithographic apparatus 1.

FIG. 7 depicts a focus system according to an embodiment of the invention. The focus system comprises the focus adjuster 60. As with the constructions depicted in FIG. 5 and FIG. 6, the radiation beam expander 40 is an optional element and may be excluded.

As depicted in FIG. 7, the focus adjuster 60 may be attached to the frame 8 via a hinge 81. The hinge 81 is configured to tilt the optical element 62 with respect to the optical path 61. In an embodiment the hinge 81 is comprised in the focus adjuster 60. In an embodiment the hinge 81 is an elastic hinge. In an embodiment an actuator 83 is configured to vary the tilt angle of the optical element 62. The tilt angle can be varied after the lithographic apparatus 1 has been initially set up. The tilt angle can be adjusted between exposure operations. In an embodiment the actuator 83 is configured to adjust the tilt angle of the optical element 62 based on measurement of a parameter of the optical path 61.

The hinge 81 allows the tilt angle α of the optical element 62 to be varied depending on the desired focal positional adjustment ds. The hinge 81 provides sufficient rigidity such that once the tilt angle α has been selected and the optical element 62 has been set in position, the tilt angle α remains substantially fixed during use of the lithographic apparatus 1. In an embodiment the tilt angle α may be adjusted by using the hinge 81 between exposure operations.

In an embodiment the optical element 62 is attached to the frame 8 via an axial adjuster 82. The axial adjuster 82 is configured to adjust the axial position of the optical element 62 along the optical path 61 relative to the frame 8. In an embodiment the controller 500 is configured to determine a desired axial position of the optical element 62. The axial adjuster 82 may then be used to move the optical element 62 to the desired axial position. In an embodiment the axial adjuster 82 comprises a threaded screw. The axial adjuster 82 is configured such that during an exposure operation the axial position of the optical element 62 remains substantially constant. The tilt angle of the optical element 62 does not vary in an uncontrolled manner due to movement of the lithographic apparatus 1 in use.

In an embodiment each focus adjuster 60 of the lithographic apparatus 1 is configured to adjust a focal position of the corresponding optical path 61 so as to form certain angular separations between the optical path 61. In this way a certain pattern, for example, may be formed on the substrate 17. The pattern formed can take account of undesirable deviation in the positions of the lenses 14, 18 of the lens group 9.

In an embodiment the lithographic apparatus 1 comprises an actuator 11 configured to cause the lens group array to rotate relative to the programmable patterning device in a plane substantially perpendicular to the optical path 61. During rotation of the lens group array, the centrifugal force can cause the radial position of one or more of the lenses to be adjusted undesirably. The focus adjuster(s) 60 can be used to correct for this undesirable deviation.

In an embodiment the lithographic apparatus 1 is set up initially without the focus adjusters 60. At least a part of the lithographic apparatus is then used. For example, the lens group array is rotated. The positional error of the radiation beam for each lens group is determined during use. Alternatively, the positional error of the radiation beam for each lens group is estimated when the lithographic apparatus 1 is not being used (e.g. without rotating the lens group array). A focus adjuster 60 is added (e.g. mounted) to each lens group as required. The corrected position of the radiation beam for each lens group is checked.

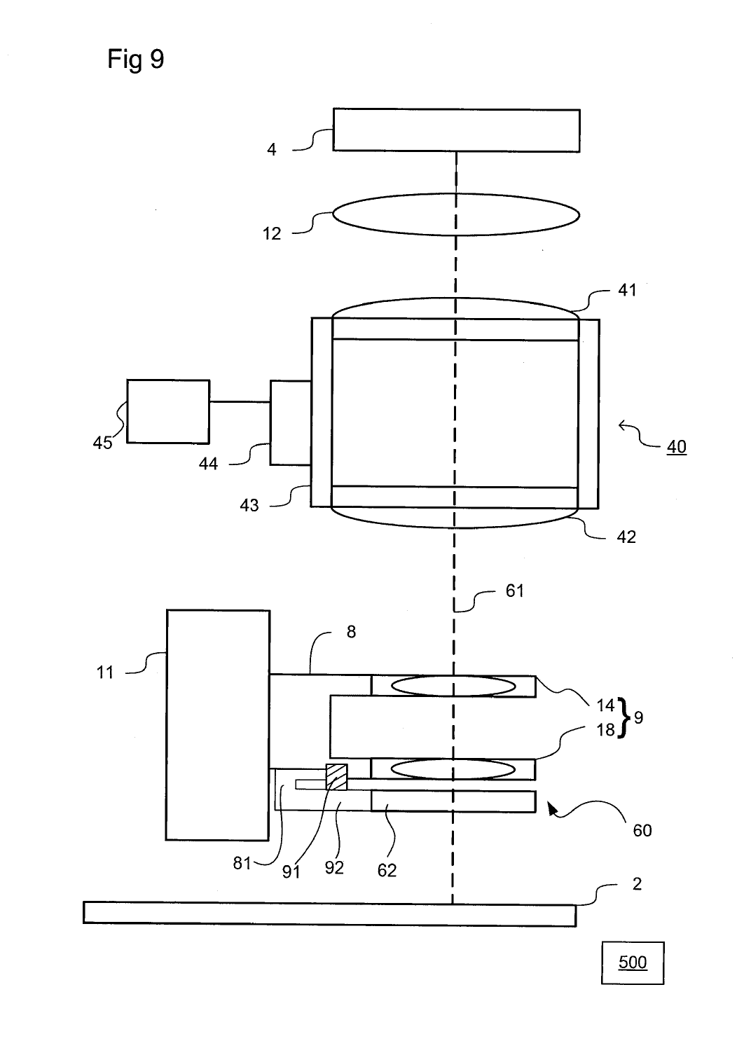

FIG. 9 depicts an embodiment in which the focus adjuster 60 is attached to the frame 8 via a hinge 81. The hinge 81 comprises a deformable material. In an embodiment the deformable material is an elastic material. In an embodiment, the optical element 62 of the focus adjuster 60 is fixed to an arm 92. The arm 92 is connected to the hinge 81. In an embodiment, the arm 92 is integral to the hinge 81. In an embodiment, the tilt angle α of the optical element 62 can be adjusted by adjusting the tilt angle of the arm 92.

As depicted in FIG. 9, in an embodiment the tilt angle α of the optical component 62 and the arm 92 is adjusted by the movement of an actuator or tilter 91. The tilter 91 moves at least partly in the axial direction. The tilter 91 is configured to change the tilting angle of the arm 92 and in turn, the optical element 62. In an embodiment, the tilter 91 changes the tilting angle of the arm 92 by making physical contact with the arm 92. In an embodiment, the tilter 91 comprises a threaded screw. The threaded screw may move in the axial direction relative to the frame 8. The threaded screw may be positioned in a bore within the frame 8.

In the embodiment depicted in FIG. 9, the tilt angle α of the optical element 62 can be adjusted before the lithographic apparatus 1 is switched on (i.e. during setup). After setup, the tilt angle α of the optical element is fixed. Hence, the tilt angle α of the optical component 62 is controlled passively.

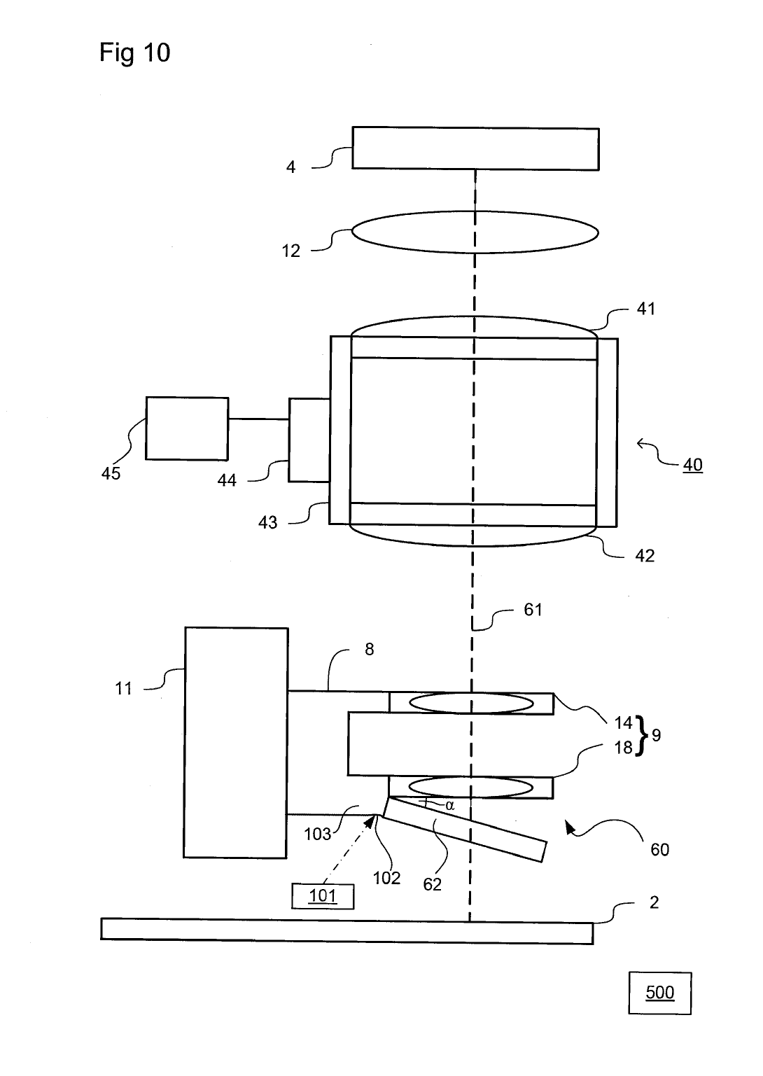

FIG. 10 depicts an embodiment in which the tilt angle α of the optical element 62 is adjusted by a different method. In an embodiment, the optical element 62 is connected to a supporting component 103. In an embodiment, the supporting component 103 is connected to a minor edge of the optical element 62. The supporting component 103 may be integral to the frame 8.

A laser output 101, connected to a laser (not shown for convenience) is configured to provide a laser beam (shown by a dot-chain line in FIG. 10) that is incident on a portion 102 of the supporting component 103. The portion 102 of the supporting component 103 on which the laser beam is incident undergoes an expansion process, followed by a yielding process, followed by a contraction process. As a result of the contraction process, the portion 102 of the supporting component 103 is bent by the application of the laser beam. The bending of the portion 102 of the supporting component 103 causes the optical component 62 to tilt with respect to the lens group 9.

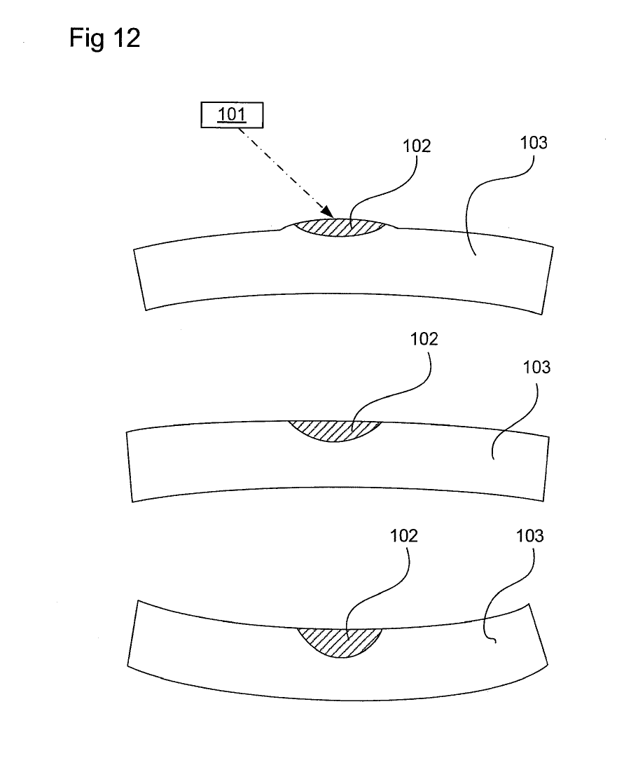

FIG. 12 illustrates the mechanism by which the supporting component 103 may be bent. Laser output 101 irradiates the portion 102 of the supporting component 103 with laser radiation. As depicted in the upper drawing of FIG. 12, the laser radiation heats the portion 102 of the supporting component 103. The portion 102 that is heated by the laser radiation comprises part of the outer surface of the supporting component 103 and extends a small distance into the supporting component 103. Only the portion 102 at and near the surface of the supporting component 103 is heated by the laser radiation. The portion 103 extends only partially through the depth of the supporting component 103.

The laser radiation heats the portion 102 at and near the surface of the supporting component 103 to a temperature at or near the melting point of the material from which the supporting component 103 is formed. As depicted in the middle drawing of FIG. 12, the portion 102 yields (i.e. at least partially melts). When the portion 102 yields, the shape of the portion changes.

The laser output 101 irradiates the portion 102 for a limited time period. After the irradiation has ceased the portion 102 cools down. As depicted in the lower drawing of FIG. 12, the contraction process takes place as the portion cools down. The contraction process results in the supporting component 103 bending.

Hence, the tilt angle α of the optical element 62 of the focus adjuster 60 can be controlled by locally melting material using laser radiation. The laser radiation should be sufficiently powerful to at least partially melt the material from which the supporting component 103 is made. In an embodiment, the supporting component 103 comprises a metal. In an embodiment the metal is steel. In an embodiment the metal is stainless steel. As depicted in FIG. 10, the laser out 101 may be configured to irradiate the supporting component 103 from below. In an embodiment, the laser output 101 is additionally or alternatively configured to irradiate the supporting component 103 from above, so as to adjust the tilt angle α of the optical component 62. The bend caused by a laser output 101 below the supporting component 103 can be reversed by the application of a laser output 101 on the opposite side of (e.g. above) the supporting component 103.

In an embodiment, a plurality of the optical components 62 of the focus adjusters 60 are connected to the same supporting component 103. In an embodiment, each of the optical components 62 is connected to the frame 8. In an embodiment, the supporting component 103 comprises a slit 111 between each neighboring pair of optical components 62, as depicted in FIG. 11. The purpose of the slit 111 is to decouple the effects of the laser adjustment on the tilting angle α of a neighboring optical component 62. Use of the slit 111 improves the independence of the control of the tilt angle α for a neighboring optical component 62. In an embodiment, each slit 111 separates neighboring optical elements 62 from each other. As a result, there is no direct, straight line between neighboring optical elements 62 through the integral supporting component 103 to which the optical elements 62 are connected. In an embodiment, the supporting component 103 comprises a wheel. The slit 111 may be radial, extending from the outer radial edge of the wheel to a position radially inwards of the optical components 62.

An advantage of using laser adjustment to control the tilt angle α is that the control of the tilt angle α can be performed when the lithographic apparatus 1 is in use. In particular, as mentioned above, the desirable corrections to be made for each lens group 9 can be measured while the lens group array is moving. By using laser adjustment, it is possible to make an adjustment while the lens group array is moving.

The above-described radiation adjustment system (i.e. adjustment through partial melting by irradiation) can be used to adjust the position and/or orientation of any optical component that is connected (either directly or indirectly) to a frame in a lithographic apparatus. In an embodiment, a lithographic apparatus comprises a radiation outlet (e.g., a radiation source having such an outlet) configured to irradiate a surface of the frame so as to at least partially melt or soften a portion 102 at and near the surface of the frame so that the portion 102 contracts as it cools, thereby adjusting the position and/or orientation of the optical component.

For example, in the context of a lithographic apparatus that comprises a programmable patterning device and a projection system comprising a lens group array as described above, the optical component is, in an embodiment, a lens 14, 18 of the lens group array. However, the optical component may be an optical component other than such a lens. For example, the optical component may be the optical element 62 of the focus adjuster 60 described above.

Furthermore, the radiation adjustment system may be used in the context of a lithographic apparatus that does not comprise a programmable patterning device and a projection system comprising a lens group array as described above. However, for clarity, the use of irradiation to adjust the position and/or orientation of an optical component is described below in the context of the optical component being a lens 14, 18 of a lens group array.

In an embodiment the radiation outlet (e.g., radiation source) is configured to heat at least one portion 102 of the frame 8 of the lithographic apparatus. The radiation can result in the bending and/or contraction of the one or more portions 102 of the frame 8 so as to adjust the position and/or orientation of the lens 14, 18.

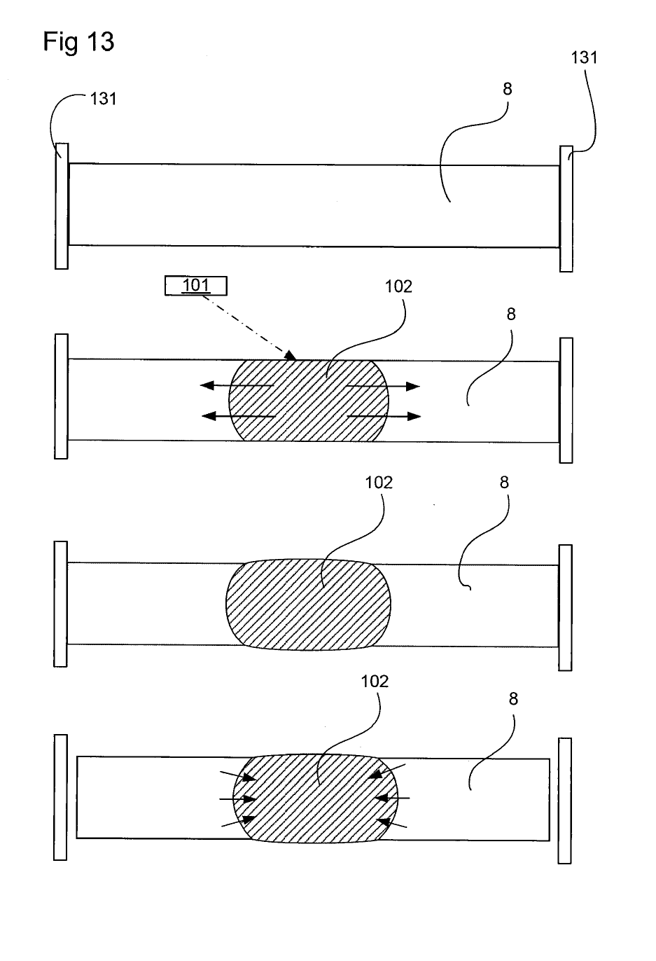

Bending of a frame 8 may be achieved as depicted in FIG. 12 and as described in the corresponding description. By this mechanism, a planar section of the frame 8 can be bent out of its plane. The shape of the frame 8 can also be adjusted within the plane of the frame 8, for example contracting a section of the frame 8. This mechanism is depicted in FIG. 13.

FIG. 13 depicts the frame 8 at different stages of undergoing contraction by irradiation from a radiation outlet. The top picture of FIG. 13 depicts the frame 8 before the irradiation. The borders 131 schematically represents the initial position of the frame 8 extending a fixed distance between the borders 131.

The second picture in FIG. 13 depicts a radiation output 101 of the radiation source irradiating a portion 102 of the frame 8. The radiation heats the portion 102 of the frame 8. The portion 102 that is heated by the radiation comprises part of the outer surface of the frame 8 and extends a short distance into the frame 8. Only the portion 102 at and near the surface of the frame 8 is heated by the radiation. The portion 102 extends only partially through the depth of the frame 8.

The radiation heats the portion 102 at and near the surface of the frame 8 to a temperature at or near the melting point of the material from which the frame is formed. The arrows in the second drawing of FIG. 13 represent the pressure for the material to expand. However the material cannot expand because it is fully enclosed by other parts of the frame 8. This enclosure is schematically represented by the borders 131 in FIG. 13. As a result of not being able to expand, the material yields. The third drawing in FIG. 13 depicts the frame 8 after the yielding process. The yielding involves the material of the frame 8 in the portion 102 at least partially melting. As depicted in FIG. 13, the shape of the portion 102 changes.

The bottom picture in FIG. 13 depicts the solidification and contraction of the portion 102 following the yielding process. The portion 102 contracts as it cools. The arrows in the bottom picture of FIG. 13 indicate the contraction of the portion 102.

If only one surface of the frame 8 is irradiated, then the contraction may result in bending of the frame 8, as depicted in FIG. 12. However, if corresponding positions of opposing surfaces of the frame 8 are irradiated in this manner, then the result of the contraction is that the length of the frame 8 decreases, without substantial bending. This is depicted in FIGS. 15 and 16, for example.

By the radiation adjustment system, it is possible to adjust the tilt angle of the lens 14, 18 by causing the frame 8 to bend appropriately. It is also possible to adjust the radial position of the lens 14, 18 by contracting the frame 8 at opposing surfaces such that the frame 8 connected to the lens 14, 18 shortens in length. It is also possible to adjust the axial position of the lens 14, 18 by causing the frame to bend at staggered positions on opposing surfaces. This is depicted in FIGS. 15 and 16.

The shape of the area to be softened (i.e. the shape of the portion 102) is not particularly limited and may be determined according to the application. In an embodiment, the area is a spot. In an embodiment, the area is a line. The line may be continuous or formed from a series of spots. The area may form a shape such as a curved line, a circle, a square, etc.

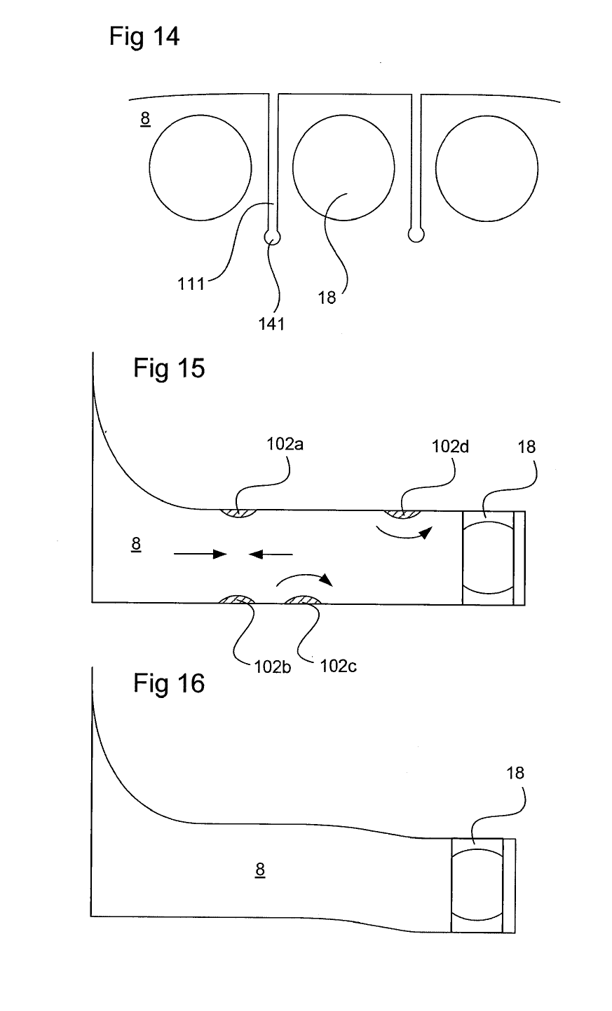

FIG. 14 depicts a section of the frame 8. The lens 14, 18 is embedded in the peripheral region of the frame 8. In an embodiment the frame 8 comprises a slit array. Each adjacent pair of lenses 14, 18 is separated by a slit 111 of the slit array. An advantage of such slits 111 is described above in relation to FIG. 11.

As depicted in FIG. 14 in an embodiment the frame 8 comprises a hole 141 in communication with the slit 111. The width (e.g., diameter) of the hole 141 is greater than the width of the slit 111. The hole 141 is connected to the radially inward end of the slit 111. The hole 141 increases the independence of each lens 14, 18 to be positioned independently of the adjacent lenses 14, 18.

FIG. 15 depicts an embodiment in which portions 102 of the frame 8 are irradiated so as to adjust the position of the lens 14, 18. Portions 102 both on the upper surface and on the lower surface of the frame 8 are irradiated. The arrows in FIG. 15 indicate the contraction of the portions 102 of the frame 8. By irradiating portions 102a and 102b, the lens 14, 18 is adjusted to a more radially inward position. This is because the radial length of the frame 8 is decreased by contractions at portions 102a and 102b. Portion 102a is directly opposite portion 102b such that irradiation of these portions does not result in substantial bending of the frame 8.

In the example depicted in FIG. 15, the frame 8 is irradiated at portions 102c and 102d. Portion 102c is staggered (i.e. offset) from portion 102d on the opposing surface of the frame 8. The result of irradiating portions 102c and 102d is depicted in FIG. 16. The irradiation at portion 102c causes the frame 8 to bend downwards at portion 102c. Irradiation at portion 102d causes the frame to bend upwards at portion 102d. The result is that the axial position of the lens 14, 18 is adjusted to be lower. This can be seen from a comparison of FIG. 15 to FIG. 16. Of course, this radiation adjustment system can be used to axially raise the lens 14, 18. Irradiation of sections 102c and 102d can adjust not only axial position, but axial position and tilt of the optical component (e.g. lens 18) simultaneously.

The amount of contraction at each portion 102 can be controlled by varying the time of irradiation and/or by varying the intensity of irradiation, for example. This radiation adjustment method allows adjustment to be made to the position and/or orientation of the lens 14, 18 and the frame 8 without significantly changing the stiffness of the frame 8 or adding any extra material.

The radiation adjustment system can be performed during rotation of the frame 8. During use of the lithographic apparatus it is possible for the position and/or orientation of the lenses 14, 18 to vary undesirably. By using the radiation adjustment system during use, it is possible to at least partially compensate for any such undesirable variation. Additionally or alternatively, the radiation adjustment system can be used to adjust the position of one or more optical components before use during a dedicated production set-up, for example. This can be done at operating frequency, i.e. with the frame 8 rotating. Hence, use of the radiation adjustment system relaxes the requirements on the predictability and uniformity of stiffness parameters of the frame. Stiffness parameters can vary due to geometrical tolerances, for example.

In an embodiment the radiation source comprises a plurality of radiation outputs 101. For example, there may be a radiation output 101 positioned above the frame 8 so as to irradiate portions 102 of the upper surface of the frame 8. Alternatively or additionally, there may be a radiation output 101 positioned below the frame 8 so as to irradiate portions of the lower surface of the frame 8. In an embodiment the radiation source comprises a radiation output 101 that may move relative to the frame 8 such that the radiation output 101 can irradiate portions 102 on both the upper surface and the lower surface of the frame 8. In an embodiment there is one or more radiation outputs 101 above the frame 8 and/or one or more radiation outputs 101 below the frame 8.

The focus of each of the beams of radiation forming a spot of radiation on the substrate should be measured. In an embodiment the focal length and/or focal position may be measured by projecting each beam or radiation onto an image sensor capable of measuring the width (e.g., diameter) of the spot of radiation. The focus may then be adjusted until the spot width is a desired size and/or the system may determine the distance from the projection system at which the spot is the desired width.

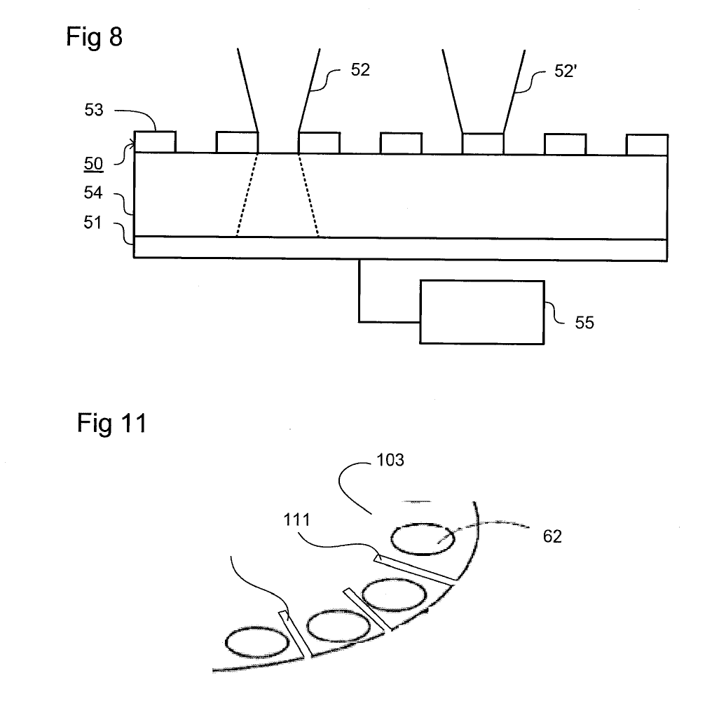

In an embodiment the focal length and/or focal position is measured by a spot focus sensor system as depicted in FIG. 8. A spot 52 of radiation is projected onto and scanned across a grating 50 such that it is incident on a plurality of locations on the grating 50. A spot 52 of radiation projected onto a gap in the grating largely passes through a substrate 54 to a radiation intensity sensor 51. A spot 52′ of radiation projected onto a chrome strip 53 used to form the grating 50 is largely prevented from passing through to the radiation intensity sensor. The greater the focus of the spot of radiation, the greater the contrast between the signal level of the radiation intensity sensor 51 at these two positions. Accordingly, a controller 55 may determine a spot focus measurement from a measure of the contrast of maximum and minimum signal levels from the radiation intensity sensor as the spot of radiation scans across the grating 50.

The spot focus sensor system depicted in FIG. 8 has an advantage of obtaining greater accuracy of the focusing system, an advantage of using a relatively inexpensive image sensor and/or an advantage of being able to perform the focus measurement quickly.

In accordance with a device manufacturing method, a device, such as a display, integrated circuit or any other item may be manufactured from the substrate on which the pattern has been projected.

Further embodiments according to the invention are provided in below numbered clauses:

1. A lithographic apparatus comprising:

a programmable patterning device, configured to provide a plurality of radiation beams; and

a projection system comprising:
a lens group array configured to project the plurality of radiation beams onto a substrate; and
a focus adjuster in an optical path corresponding to a lens group of the lens group array, the focus adjuster comprising an optical element having substantially zero optical power.
   2. The lithographic apparatus of clause 1, wherein the focus adjuster is configured to adjust a focal length of the optical path.
   3. The lithographic apparatus of any of the preceding clauses, wherein the focus adjuster is configured to adjust a focal length of the optical path to be substantially equal to a focal length of an optical path of a different lens group of the lens group array.
   4. The lithographic apparatus of any of the preceding clauses, wherein the focus adjuster is configured to adjust a focal position of the optical path.
   5. The lithographic apparatus of any of the preceding clauses, wherein the optical element comprises an entry surface and an exit surface through which the radiation beams enter and exit the optical element, respectively, wherein the entry surface and the exit surface are substantially flat surfaces.
   6. The lithographic apparatus of any of the preceding clauses, wherein the optical element of the focus adjuster is configured to be the last optical element in the optical path.
   7. The lithographic apparatus of any of the preceding clauses, wherein the focus adjuster is configured to shift the optical path.
   8. The lithographic apparatus of any of the preceding clauses, wherein the focus adjuster is attached to a frame.
   9. The lithographic apparatus of clause 8, wherein the frame is provided with the lens group array.
   10. The lithographic apparatus of clause 8 or clause 9, wherein the focus adjuster is attached to the frame such that the optical element is fixed at a tilted orientation with respect to the optical path.
   11. The lithographic apparatus of any of clauses 8 to 10, wherein the optical element is attached to the frame via a hinge configured to tilt the optical element with respect to the optical path.
   12. The lithographic apparatus of clause 11, comprising an actuator configured to move and press against an arm to which the optical component is attached so as to adjust the tilted orientation of the optical element via the hinge.
   13. The lithographic apparatus of any of clauses 8 to 12, wherein the optical element is attached to the frame via an adjuster configured to adjust the position of the optical element along the optical path relative to the frame.
   14. The lithographic apparatus of any of clauses 8 to 13, wherein the optical element is attached to the frame via a supporting component, and further comprising a laser output configured to irradiate a surface of the supporting component so as to at least partially melt a
   portion at and near the surface of the supporting component so that the supporting component bends as it cools, thereby adjusting the tilted orientation of the optical element.
   15. The lithographic apparatus of any of the preceding clauses, wherein the focus adjuster comprises a tube extending along the optical path, the tube housing the optical element fixedly tilted with respect to the optical path.
   16. The lithographic apparatus of any of the preceding clauses, wherein the optical element is rotatable around the optical path as the axis of rotation.
   17. The lithographic apparatus of any of the preceding clauses, wherein the projection system comprises a plurality of the focus adjusters, each in a corresponding optical path corresponding to a lens group of the lens group array.
   18. The lithographic apparatus of clause 17, wherein each focus adjuster is configured to adjust a focal length of the corresponding optical path such that all of the optical paths have substantially the same focal length.
   19. The lithographic apparatus of clause 17 or clause 18, wherein each focus adjuster is configured to adjust a focal position of the corresponding optical path so as to form a certain angular separation between the optical paths.
   20. A lithographic apparatus comprising:

an optical component connected to a frame; and

a radiation output configured to irradiate a surface of the frame so as to at least partially melt a portion at and near the surface of the frame so that the portion contracts as it cools, thereby adjusting the position and/or orientation of the optical component.

21. The lithographic apparatus of clause 20, comprising a plurality of optical components, wherein the frame comprises a slit array such that each adjacent pair of optical components is separated by a slit of the slit array.
22. The lithographic apparatus of clause 20 or clause 21, wherein the radiation output is configured to irradiate an upper surface of the frame and/or the radiation output is configured to irradiate a lower surface of the frame.
23. The lithographic apparatus of any of clauses 20 to 22, comprising:

a programmable patterning device, configured to provide a plurality of radiation beams; and

a projection system comprising a lens group array configured to project the plurality of radiation beams onto a substrate.

24. The lithographic apparatus of clause 23, wherein the optical component is a lens of the lens group array.
25. The lithographic apparatus of any of clauses 1 to 19, 23 or 24, wherein the projection system is configured to move the array of lenses with respect to the programmable patterning device during exposure of the substrate.
26. The lithographic apparatus of any of clauses 1 to 19, 23, 24 or 25, comprising an actuator configured to cause the array of lenses to rotate relative to the programmable patterning device in a plane substantially perpendicular to the optical path.
27. A method of setting up a lithographic apparatus, the lithographic apparatus comprising:

a programmable patterning device, configured to provide a plurality of radiation beams, and

a projection system comprising a lens group array configured to project the plurality of radiation beams onto a substrate, the method comprising:
measuring, for each of a plurality of lens groups of the lens group array, a parameter of an optical path corresponding to the lens group; and
providing in each optical path a focus adjuster comprising an optical element having substantially zero optical power.
   28. A device manufacturing method comprising:

the method of setting up a lithographic apparatus according to clause 27; and using the set up lithographic apparatus to manufacture a device.

29. A device manufacturing method comprising:

providing a plurality of radiation beams; and

projecting the plurality of radiation beams onto a substrate through a lens group array, wherein the plurality of radiation beams are projected onto the substrate via a focus adjuster comprising an optical element having substantially zero optical power in an optical path of a corresponding lens group of the lens group array.

30. A method of adjusting a position and/or orientation of an optical component, connected to a frame, of a lithographic apparatus comprising:

irradiating a surface of the frame so as to at least partially melt a portion at and near the surface of the frame so that the portion contracts as it cools, thereby adjusting the position and/or orientation of the optical component.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

While specific embodiments of the invention have been described above, it will be appreciated that the invention may be practiced otherwise than as described. For example, the embodiments of the invention may take the form of a computer program containing one or more sequences of machine-readable instructions describing a method as disclosed above, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

The term “lens”, where the context allows, may refer to any one of various types of optical components, including refractive, diffractive, reflective, magnetic, electromagnetic and electrostatic optical components or combinations thereof.

The descriptions above are intended to be illustrative, not limiting. Thus, it will be apparent to one skilled in the art that modifications may be made to the invention as described without departing from the scope of the claims set out below.

1. A lithographic apparatus comprising:
a programmable patterning device, configured to provide a plurality of radiation beams; and
a projection system comprising:
a lens group array configured to project the plurality of radiation beams onto a substrate; and
a focus adjuster in an optical path corresponding to a lens group of the lens group array, the focus adjuster comprising an optical element having substantially zero optical power.

2. The lithographic apparatus of claim 1, wherein the focus adjuster is configured to adjust a focal length of the optical path.

3. The lithographic apparatus of claim 1, wherein the focus adjuster is configured to adjust a focal position of the optical path.

4. The lithographic apparatus of claim 1, wherein the optical element comprises an entry surface and an exit surface through which the radiation beams enter and exit the optical element, respectively, wherein the entry surface and the exit surface are substantially flat surfaces.

5. The lithographic apparatus of claim 1, wherein the focus adjuster is attached to a frame.

6. The lithographic apparatus of claim 5, wherein the optical element is attached to the frame via a supporting component, and further comprising a laser output configured to irradiate a surface of the supporting component so as to at least partially melt a portion at and near the surface of the supporting component so that the supporting component bends as it cools, thereby adjusting the tilted orientation of the optical element.

7. The lithographic apparatus of claim 1, wherein the projection system comprises a plurality of the focus adjusters, each in a corresponding optical path corresponding to a lens group of the lens group array.

8. The lithographic apparatus of claim 7, wherein each focus adjuster is configured to adjust a focal length of the corresponding optical path such that all of the optical paths have substantially the same focal length.

9. The lithographic apparatus of claim 7, wherein each focus adjuster is configured to adjust a focal position of the corresponding optical path so as to form a certain angular separation between the optical paths.

10. A lithographic apparatus comprising:
an optical component connected to a frame; and
a radiation output configured to irradiate a surface of the frame so as to at least partially melt a portion at and near the surface of the frame so that the portion contracts as it cools, thereby adjusting the position and/or orientation of the optical component.

11. The lithographic apparatus of claim 10, comprising a plurality of optical components, wherein the frame comprises a slit array such that each adjacent pair of optical components is separated by a slit of the slit array.

12. The lithographic apparatus of claim 1, wherein the projection system is configured to move the array of lenses with respect to the programmable patterning device during exposure of the substrate.

13. The lithographic apparatus of claim 1, comprising an actuator configured to cause the array of lenses to rotate relative to the programmable patterning device in a plane substantially perpendicular to the optical path.

14. A method of setting up a lithographic apparatus, the lithographic apparatus comprising:
a programmable patterning device, configured to provide a plurality of radiation beams, and
a projection system comprising a lens group array configured to project the plurality of radiation beams onto a substrate,
the method comprising:
measuring, for each of a plurality of lens groups of the lens group array, a parameter of an optical path corresponding to the lens group; and
providing in each optical path a focus adjuster comprising an optical element having substantially zero optical power.

15. A device manufacturing method comprising:
the method of setting up a lithographic apparatus as claimed in claim 14; and
using the set up lithographic apparatus to manufacture a device.

16. A device manufacturing method comprising:
providing a plurality of radiation beams; and
projecting the plurality of radiation beams onto a substrate through a lens group array, wherein the plurality of radiation beams are projected onto the substrate via a focus adjuster comprising an optical element having substantially zero optical power in an optical path of a corresponding lens group of the lens group array.

17. A method of adjusting a position and/or orientation of an optical component, connected to a frame, of a lithographic apparatus, the method comprising:
irradiating a surface of the frame so as to at least partially melt a portion at and near the surface of the frame so that the portion contracts as it cools, thereby adjusting the position and/or orientation of the optical component.
